(19) United States
(12) Patent Application Publication
(10) Pub. No.: US 2023/0120428 A1
(43) Pub. Date: Apr. 20, 2023

(54) SILICON-BASED MICRO DISPLAY SCREEN AND METHOD FOR MANUFACTURING THE SAME

(71) Applicant: KUNSHAN FANTAVIEW ELECTRONIC TECHNOLOGY CO., LTD., Suzhou City, Jiangsu Province (CN)

(72) Inventors: XIAOSONG DU, Suzhou City, Jiangsu Province (CN); XIAOLONG YANG, Suzhou City, Jiangsu Province (CN); WENBIN ZHOU, Suzhou City, Jiangsu Province (CN); FENG ZHANG, Suzhou City, Jiangsu Province (CN); JIAN SUN, Suzhou City, Jiangsu Province (CN); YUDI GAO, Suzhou City, Jiangsu Province (CN)

(21) Appl. No.: 17/044,844

(22) PCT Filed: Apr. 30, 2020
(86) PCT No.: PCT/CN2020/088202

§ 371 Date: Oct. 1, 2020

(30) Foreign Application Priority Data
Nov. 18, 2019 (CN) 201911125609.0

(51) Int. Cl. H10K 59/80; H10K 71/20; H10K 71/60; H10K 59/12; H01L 23/14

(52) U.S. Cl. CPC H10K 59/873; H10K 71/231; H10K 71/60; H10K 59/1201; H10K 59/8051; H10K 59/8052; H01L 23/147; H10K 2102/103

(57) ABSTRACT

The present invention provides a silicon-based micro display screen and method for manufacturing the same. The method includes following steps: providing a silicon substrate, defining a number of sub-pixel regions on the silicon substrate, and sequentially and respectively preparing an anode layer, an OLED layer, a cathode layer and a first protective layer in each sub-pixel region on the silicon substrate; plasma bombarding and removing the exposed OLED layer; forming a second protective layer on sides of the etched cathode layer, the protective layer and the OLED layer; sequentially performing other sub-pixels; and processing and forming a silicon-based micro-display screen based on the results of the above steps. In present invention, the etching and coating processes are carried out in a vacuum environment to prevent the OLED layer from being invaded by water vapor and oxygen, and prolong the service life of the silicon-based micro display screen.

### CROSS-REFERENCE TO RELATED INVENTIONS

This invention is an application which claims the priority of CN application Serial No. 201911125609.0, filed on Nov. 18, 2019, and titled as “SILICON-BASED MICRO DISPLAY SCREEN AND METHOD FOR MANUFACTURING THE SAME”, the disclosures of which are hereby incorporated by reference in their entirety.

### BACKGROUND

### 1. Technical Field

The invention relates to the field of manufacturing of the OLED (Organic Light-Emitting Diode) display, in particular to silicon-based micro display screen and method for manufacturing the same.

### 2. Description of Related Art

Compared with CTR (Cathode Ray Tube) displays and TFT-LCD (Thin Film Transistor-Liquid Crystal Displays), the OLED displays have lighter and thinner design, wider viewing angle, faster response speed and lower power consumption, so that OLED displays have gradually attracted people's attention as the next generation of display devices.

Most of the current OLED display screens use evaporation of different OLED materials to achieve OLED graphics. This method is no problem when the pixel density is lower than 700 PPI. However, when the pixel density is greater than 800 PPI, the existing manufacturing technology will enter a physical bottleneck, and there is a problem of difficulty in high PPI patterning.

In addition, the organic materials used in OLEDs are particularly sensitive to water and oxygen, and are very easy to react with the infiltrating water vapor, affecting the injection of charges. The infiltrating water vapor and oxygen will also chemically react with organic materials. These reactions are main factors causing the performance degradation and shortening of the life of OLED devices. Therefore, OLED devices require strict packaging materials to protect them from water and oxygen.

Hence, there is a need to provide a new silicon-based micro display screen and corresponding method for manufacturing the same to solve the problems.

### SUMMARY

The objective of the present invention is to provide a method for manufacturing a silicon-based micro display screen. The silicon-based micro display screen is prepared by placing the etching and coating processes in a vacuum environment to prevent the OLED layer from being invaded by water vapor and oxygen, and the service life of the silicon-based micro display is extended.

In order achieve above-mentioned objectives, the present invention provides a method of manufacturing silicon-based micro display screen, characterized in that, the method comprises following steps:

S1: providing a silicon substrate, defining a plurality of sub-pixel regions on the silicon substrate, and preparing an anode layer in each sub-pixel region on the silicon substrate;

S2: evaporating an OLED layer, a cathode layer, and a first protective layer respectively and sequentially in the sub-pixel region to cover the anode layer and the silicon substrate;

S3: etching the cathode layer and the protective layer in a first sub-pixel region by yellow light process and etching process;

S4: plasma bombarding and removing the exposed OLED layer;

S5: forming a second protective layer on sides of the etched cathode layer, the protective layer and the OLED layer to complete the production of a first sub-pixel;

S6: sequentially performing the above steps S3 to S5 on other sub-pixel regions until each sub-pixel is formed; and

S7: processing and forming a silicon-based micro-display screen based on the results of the above steps.

As an improvement of the present invention, wherein the step S1 specifically comprises following steps:

S11: providing a silicon substrate, defining a plurality of sub-pixel regions on the silicon substrate, and preparing a plurality of regularly arranged via holes in the sub-pixel region;

S12: evaporating an anode layer on the silicon substrate by using a self-aligning process, wherein the anode layer comprises anode units corresponding to the via holes one-to-one, and the width of the anode unit is 5 micrometers.

As an improvement of the present invention, wherein the etching process in step S3 and step S4, S5 are performed in a vacuum environment, and wherein the etching process is a reactive ion etching process, the process temperature of the yellowing process is lower than 90° C., and the plasma is argon ion.

As an improvement of the present invention, wherein the step S5 specifically comprises following steps:

S51: forming a second protective layer, which covers the first protective layer and the silicon substrate;

S52: etching the second protective layer by using the Spacer etching process so that only the portions of the second protective layer located on the sides of the anode layer, the OLED layer, the cathode layer and the first protective layer are remained.

As an improvement of the present invention, wherein in the step S5, material of the first protective layer is SiO₂ and material of the second protective layer is SiN.

As an improvement of the present invention, wherein the step S7 specifically comprises:

S71: forming conductive holes penetrating each first protective layer;

S72: forming a cathode connection layer in the conductive hole and gap between sub-pixels to connect the cathode layer of each sub-pixel;

S73: forming an encapsulation layer covering the silicon substrate and each sub-pixel.

As an improvement of the present invention, wherein the cathode connection layer of S72 is formed by an atomic layer deposition method, and the material is aluminum, and the thickness of the cathode connecting layer is 10 mm.

As an improvement of the present invention, wherein the etching process of step S3, and steps S4 and S5 are performed in an etching and coating linkage system, which comprises a transfer chamber, an etching chamber connected to the transfer chamber 101 and a coating chamber, and wherein inside of the etching and coating linkage system is in vacuum state.

As an improvement of the present invention, wherein the etching and coating linkage system also comprises a pre-sample transfer chamber connected to the transfer chamber and a cooling chamber.

As an improvement of the present invention, wherein the etching chamber comprises a first etching chamber for etching the first protective layer and the second protective layer, a second etching chamber for etching the cathode layer, and a third etching chamber for etching the OLED layer.

The other objective of the present invention is to provide a silicon-based micro display screen with a long service life.

In order achieve above-mentioned objective, the present invention also provides a silicon-based micro display screen, comprising a silicon substrate, a plurality of sub-pixel formed on the silicon substrate and an encapsulation layer completely covering the silicon substrate and the sub-pixels, the sub-pixel comprising an anode layer, OLED layer, a cathode layer, a first protective layer and a second protective layer, the second protective layer arranged at sides of the anode layer, the OLED layer, the cathode layer and the first protective layer, characterized in that, the silicon-based micro display screen is manufactured by method of manufacturing silicon-based micro display screen as described in above.

As an improvement of the present invention, further comprising a cathode connection layer, wherein the first protective layer is provided with a conductive hole penetrated therethrough, the cathode connection layer is disposed in the conductive hole and gap between the sub-pixels, and wherein the sub-pixel pitch is 8 micrometers.

As an improvement of the present invention, wherein the material of the cathode layer is aluminum, the material of the first protective layer is SiO2, and the material of the second protective layer is SiN, and the material of the encapsulation layer is SiO2.

As an improvement of the present invention, wherein the OLED layer comprises an organic light emitting layer, a hole injection layer and a hole transport layer located between the anode layer and the organic light emitting layer, and an electron injection layer and an electron transport layer located between the cathode layer and the organic light emitting layer.

The beneficial effects of the present invention are: the method for preparing the silicon-based micro display screen of the present invention places the etching and coating processes in a vacuum environment, prevents the OLED layer from being invaded by water vapor and oxygen, and prolongs the service life of the silicon-based micro display screen.

### BRIEF DESCRIPTION OF THE DRAWINGS

FIG. 1 is a structural schematic diagram of a silicon-based micro display screen of the present invention.

FIG. 2 is a schematic flow chart of the method for manufacturing the silicon-based micro display screen of the present invention.

FIG. 3 is a structural schematic diagram of a semi-finished product formed in step S1 of the present invention.

FIG. 4 is a structural schematic diagram of a semi-finished product formed in step S2 of the present invention.

FIG. 5 is a structural schematic diagram of a semi-finished product formed in step S3 of the present invention.

FIG. 6 is a structural schematic diagram of a semi-finished product formed in step S4 of the present invention.

FIG. 7 is a structural schematic diagram of a semi-finished product formed in step S51 of the present invention.

FIG. 8 is a structural schematic diagram of a semi-finished product formed in step S52 of the present invention.

FIG. 9 is a structural schematic diagram of a semi-finished product formed in step S6 of the present invention.

FIG. 10 is a structural schematic diagram of a semi-finished product formed in step S71 of the present invention.

FIG. 11 is a structural schematic diagram of a semi-finished product formed in step S72 of the present invention.

FIG. 12 is a structural schematic diagram of a semi-finished product formed in step S73 of the present invention.

FIG. 13 is a structural schematic diagram of an etching and coating linkage system of the present invention.

### DETAILED DESCRIPTION OF THE ILLUSTRATED EMBODIMENT

Reference will now be made to the drawing figures to describe the embodiments of the present disclosure in detail. In the following description, the same drawing reference numerals are used for the same elements in different drawings.

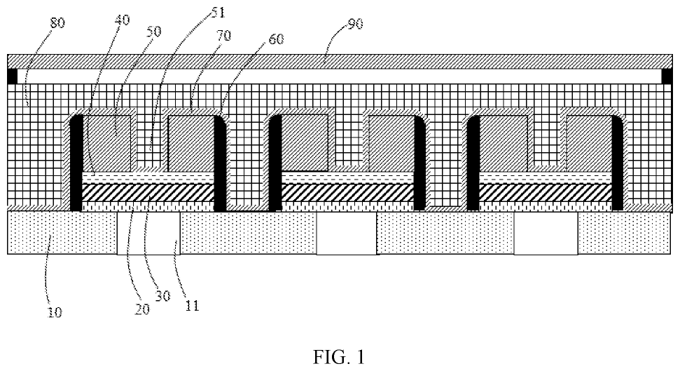

Referring to FIG. 1, the present invention provides a silicon-based micro display screen, which includes: a silicon substrate 10, a plurality of sub-pixels formed on the silicon substrate 10, and an encapsulation layer 80 that completely covers the silicon substrate 10 and the sub-pixels, and a glass plate 90 disposed above the encapsulation layer 80. The sub-pixel includes an anode layer 20, an OLED layer 30, a cathode layer 40, a first protective layer 50, and a second protective layer 60. The second protective layer 60 is provided on sides of the anode layer 20, the OLED layer 30, the cathode layer 40, and the first protective layer 50. Material of the cathode layer 40 is preferably aluminum, Material of the first protective layer 50 is preferably SiO₂, and Material of the second protective layer 60 is preferably SiN.

Specifically, the silicon substrate 10 is provided with a plurality of regularly arranged via holes 11. The anode layer 20 includes a plurality of anode units 21, and the anode units 21 are arranged in a pixel pattern on the anode layer 20. The anode unit 21 corresponds to the via holes 11 one-to-on and material of the anode unit 21 is indium tin oxide film (ITO). In this embodiment, the width of the anode unit 21 is 5 micrometers, and the sub-pixel pitch is 8 micrometers, but this should not be a limitation.

The OLED layer 30 includes an organic light emitting layer, a hole injection layer and a hole transport layer located between the anode layer 20 and the organic light emitting layer, and an electron injection layer and an electron transport layer located between the cathode layer 40 and the organic light emitting layer. Further, the hole transport layer is located between the organic light emitting layer and the hole injection layer; the electron transport layer is located between the organic light emitting layer and the electron injection layer.

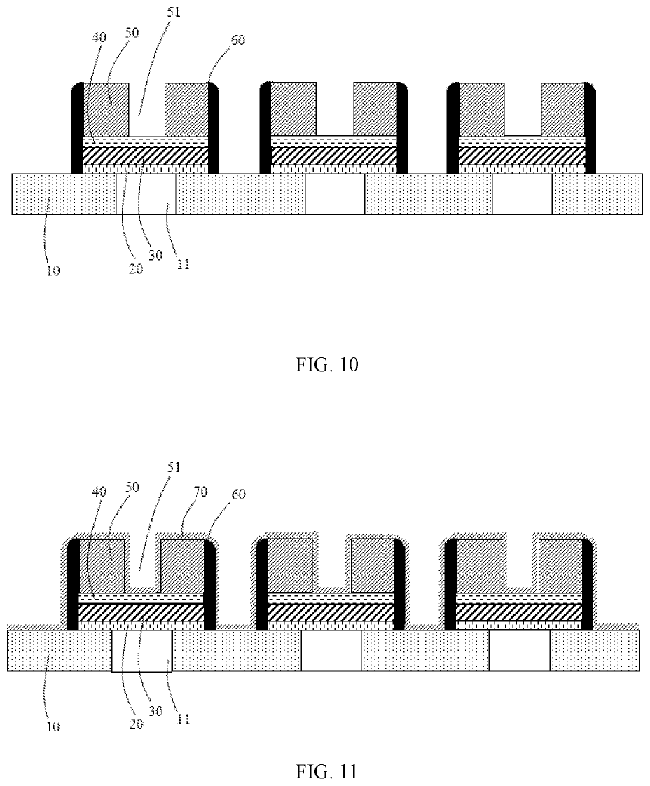

The silicon-based micro display screen of the present invention also includes a cathode connection layer 70. Together referring to FIG. 10, the first protective layer 50 is provided with a conductive hole 51 penetrating therethrough. The cathode connection layer 70 is provided in the conductive hole 51 and gap between the sub-pixels, to thereby connecting the cathode layers 40 of the plurality of sub-pixels. The material of the cathode connection layer 70 is aluminum.

The encapsulation layer 80 can be an organic film, an inorganic film, or an inorganic film stacked on an organic film. Preferably, the encapsulation layer 80 is SiO2. The encapsulation layer 80 completely covers the first protective layer 50 and the silicon substrate 10 to encapsulate the etched silicon-based micro display screen.

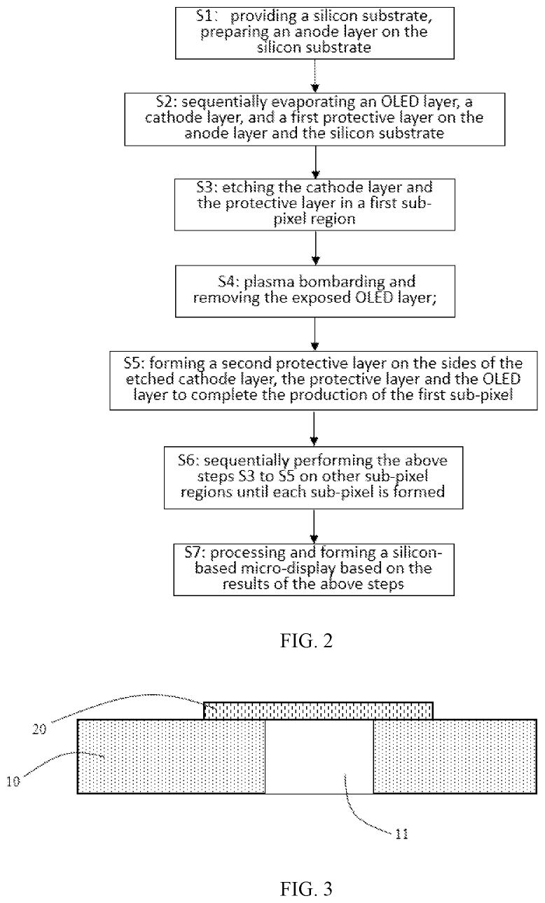

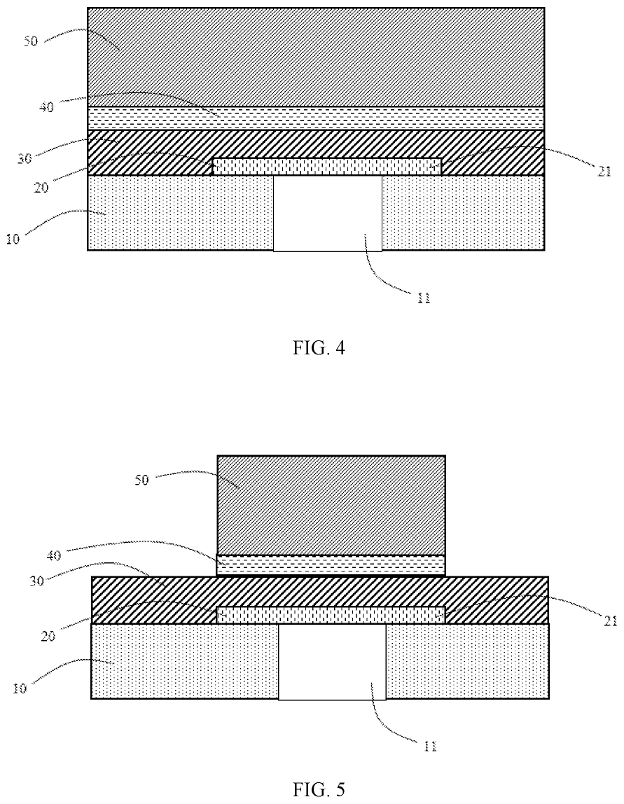

Referring to FIG. 2 to FIG. 11, the silicon-based micro display screen of the present invention is produced by following steps:

S1: providing a silicon substrate, defining a plurality of sub-pixel regions on the silicon substrate, and preparing an anode layer in each sub-pixel region on the silicon substrate;

S2: evaporating an OLED layer, a cathode layer, and a first protective layer respectively in the sub-pixel region to cover the anode layer and the silicon substrate;

S3: etching the cathode layer and the protective layer in a first sub-pixel area by yellow light process and etching process;

S4: plasma bombarding and removing the exposed OLED layer;

S5: forming a second protective layer on the sides of the etched cathode layer, the protective layer and the OLED layer to complete the production of the first sub-pixel;

S6: sequentially performing the above steps S3 to S5 on other sub-pixel regions until each sub-pixel is formed;

S7: processing and forming a silicon-based micro-display based on the results of the above steps.

Referring to FIG. 3, the step S1 specifically includes:

S11: providing a silicon substrate, defining a plurality of sub-pixel regions on the silicon substrate 10, and preparing a plurality of regularly arranged via holes 11 in the sub-pixel regions;

S12: evaporating an anode layer 20 on the silicon substrate 10 by using a self-aligning process, wherein the anode layer 20 includes anode units 21 corresponding to the via holes 11 one-to-one.

Referring to FIG. 5, the step S3 specifically includes:

S31: coating photoresist on the first protective layer 50 and curing;

S32: covering a photolithography mask on the cured photoresist, exposing and developing the photoresist to expose the area to be etched of the first protective layer 50;

S33: removing the exposed first protective layer 50 and the cathode layer 40 corresponding to the exposed first protective layer 50 by using a reactive ion etching process;

Step S34: removing the photoresist remained on the first protective layer 50.

In step S31, the photoresist can be positive or negative according to actual needs, which is not limited here.

Preferably, in step S32, a material of the photolithography mask is SiO2.

The etching process in step S3 and step S4 are performed in a vacuum environment to prevent the OLED layer from contacting water vapor and oxygen during the etching process. In addition, it should be noted that in step S3, a low-temperature curing photoresist is selected, so that the process temperature of the yellowing process is lower than 90° C.

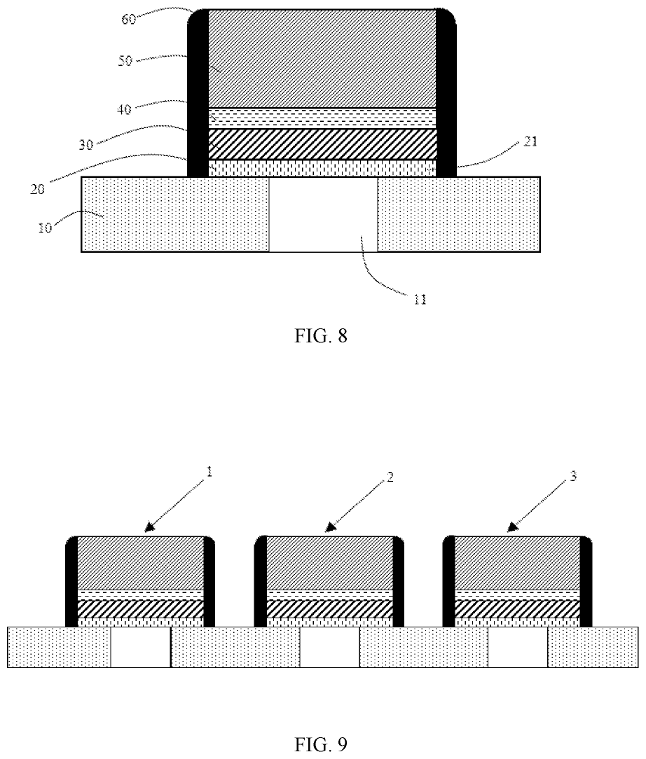

Referring to FIG. 7 and FIG. 8, the step S5 specifically includes:

S51: forming a second protective layer 60, which covers the first protective layer 50 and the silicon substrate 10;

S52: etching the second protective layer 60 by using the Spacer etching process so that only the portions of the second protective layer 60 located on the sides of the anode layer 20, the OLED layer 30, the cathode layer 40 and the first protective layer 50 remain. Among them, the Spacer etching specifically uses an anisotropic dry etching process. Due to its anisotropic characteristics, during the etching process, the etching effect on the side of the second protective layer 60 is small, so the side of the second protective layer 60 can be retained.

In step S6, a plurality of sub-pixels 1, 2, 3 . . . are formed, referring to FIG. 9.

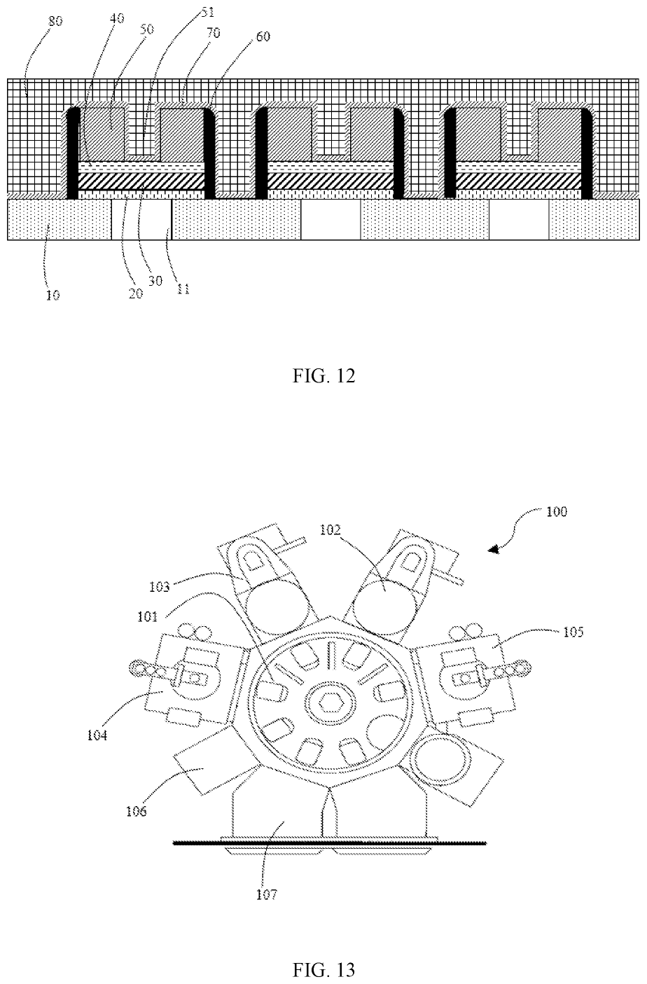

Referring to FIG. 10 to FIG. 12, the step S7 specifically includes:

S71: forming conductive holes 51 penetrating each first protective layer 50;

S72: forming a cathode connection layer 70 in the conductive hole 51 and the gap between sub-pixels to connect the cathode layer 40 of each sub-pixel;

S73: forming an encapsulation layer 80 covering the silicon substrate 10 and each sub-pixel.

Among them, step S71 specifically uses yellow light process and reactive ion etching to etch the first protective layer to form the conductive holes 51; the principle of this step is the same as that of step S3, and the specific steps are not repeated here. In step S72, the cathode connecting layer 70 is formed by an atomic layer deposition method, and the material is aluminum, and the thickness of the cathode connecting layer 70 is 10 mm, but it is not limited to this.

In the above steps, steps S33 to S5 are all performed in a vacuum environment, preferably, steps S33 to S5 are all performed in the etching and coating linkage system 100. Please refer to FIG. 13, the etching and coating linkage system 100 includes a transfer chamber 101 and a pre-sample transfer chamber 107 connected to the transfer chamber 101, an etching chamber, a coating chamber 105 and a cooling chamber 106.

The etching chamber includes a first etching chamber 102, a second etching chamber 103, and a third etching chamber 104. A semi-finished product formed in step S32 first enters the etching and coating linkage system 100 through the pre-sample transfer chamber 107. Sequentially, the first protective layer 50 is etched in the first etching chamber 102, the cathode layer 40 is etched in the second etching chamber 103, and the OLED layer 30 is etched in the third etching chamber 104, and then transferred to the coating chamber 105 to form the second protective layer 60 to prevent the water and oxygen failure of the OLED layer 30. The semi-finished product is further transferred to the first etching chamber 102 for Spacer etching. In addition, the etching and coating linkage system 100 is kept in a vacuum state to prevent the OLED layer 30 from being invaded by water vapor and oxygen during the manufacturing process.

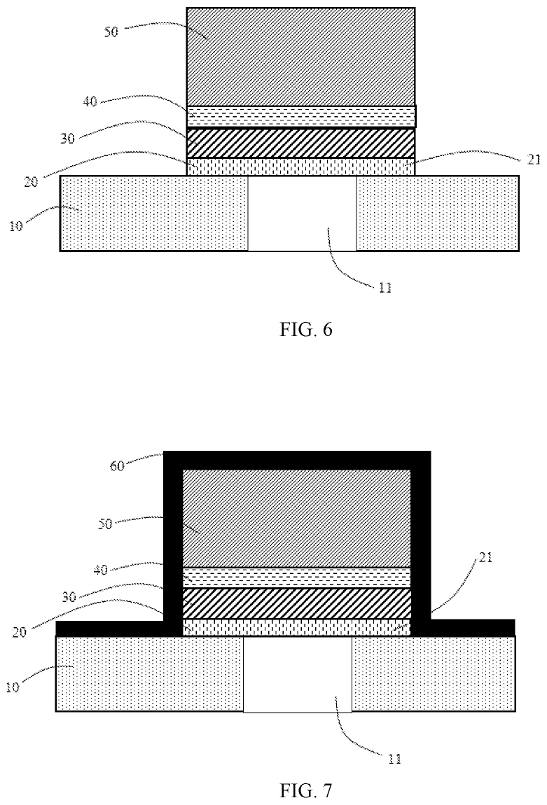

The plasma bombardment of step S4 is performed in the third etching chamber 104. First, the radio frequency power supply is used to apply sufficient energy to the gas under a certain pressure to make it ionized into a plasma state, generating a high-energy disordered plasma, and bombarding the exposed OLED layer by plasma to remove the exposed OLED (FIG. 6). In the present invention, it is preferable that the argon gas is plasmaized, that is, the plasma is argon ions.

In addition, the method for manufacturing the silicon-based micro display screen of the present invention further includes a step of arranging a glass plate 90 on the encapsulation layer 80, and connecting the glass plate 90 to the encapsulation layer 80 by UV glue. This step is conventional step, so it will not be repeated here.

In summary, the present invention uses yellow light technology and etching technology to achieve high-resolution silicon-based micro-display graphics, breaks through the physical limits of conventional evaporation patterning, and realizes high pixel density display; the etching and coating linkage system 100 is adopted to perform etching and coating in a vacuum environment to protect the OLED layer, prevent the OLED layer from being invaded by water vapor and oxygen during the preparation process, and prolong the service life of the silicon-based micro display screen.

It is to be understood, however, that even though numerous characteristics and advantages of preferred and exemplary embodiments have been set out in the foregoing description, together with details of the structures and functions of the embodiments, the disclosure is illustrative only; and that changes may be made in detail within the principles of present disclosure to the full extent indicated by the broadest general meaning of the terms in which the appended claims are expressed.

1. A method of manufacturing silicon-based micro display screen, wherein the method comprises following steps:
S1: providing a silicon substrate, defining a plurality of sub-pixel regions on the silicon substrate, and preparing an anode layer in each sub-pixel region on the silicon substrate;
S2: evaporating an OLED layer, a cathode layer, and a first protective layer respectively and sequentially in the sub-pixel region to cover the anode layer and the silicon substrate;
S3: etching the cathode layer and the protective layer in a first sub-pixel region by yellow light process and etching process;
S4: plasma bombarding and removing the exposed OLED layer;
S5: forming a second protective layer on sides of the etched cathode layer, the protective layer and the OLED layer to complete the production of a first sub-pixel;
S6: sequentially performing the above steps S3 to S5 on other sub-pixel regions until each sub-pixel is formed; and
S7: processing and forming a silicon-based micro-display screen based on the results of the above steps.

2. The method of manufacturing silicon-based micro display screen as claimed in claim 1, wherein the step S1 specifically comprises following steps:
S11: providing a silicon substrate, defining a plurality of sub-pixel regions on the silicon substrate, and preparing a plurality of regularly arranged via holes in the sub-pixel region;
S12: evaporating an anode layer on the silicon substrate by using a self-aligning process, wherein the anode layer comprises anode units corresponding to the via holes one-to-one, and the width of the anode unit is 5 micrometers.

3. The method of manufacturing silicon-based micro display screen as claimed in claim 1, wherein the etching process in step S3 and step S4, S5 are performed in a vacuum environment, and wherein the etching process is a reactive ion etching process, the process temperature of the yellowing process is lower than 90° C., and the plasma is argon ion.

4. The method of manufacturing silicon-based micro display screen as claimed in claim 1, wherein the step S5 specifically comprises following steps:
S51: forming a second protective layer, which covers the first protective layer and the silicon substrate;
S52: etching the second protective layer by using the Spacer etching process so that only the portions of the second protective layer located on the sides of the anode layer, the OLED layer, the cathode layer and the first protective layer are remained.

5. The method of manufacturing silicon-based micro display screen as claimed in claim 4, wherein in the step S5, material of the first protective layer is SiO₂ and material of the second protective layer is SiN.

6. The method of manufacturing silicon-based micro display screen as claimed in claim 1, wherein the step S7 specifically comprises:
S71: forming conductive holes penetrating each first protective layer;
S72: forming a cathode connection layer in the conductive hole and gap between sub-pixels to connect the cathode layer of each sub-pixel;
S73: forming an encapsulation layer covering the silicon substrate and each sub-pixel.

7. The method of manufacturing silicon-based micro display screen as claimed in claim 6, wherein the cathode connection layer of S72 is formed by an atomic layer deposition method, and the material is aluminum, and the thickness of the cathode connecting layer is 10 mm.

8. The method of manufacturing silicon-based micro display screen as claimed in claim 3, wherein the etching process of step S3, and steps S4 and S5 are performed in an etching and coating linkage system, which comprises a transfer chamber, an etching chamber connected to the transfer chamber and a coating chamber, and wherein inside of the etching and coating linkage system is in vacuum state.

9. The method of manufacturing silicon-based micro display screen as claimed in claim 8, wherein the etching and coating linkage system also comprises a pre-sample transfer chamber connected to the transfer chamber and a cooling chamber.

10. The method of manufacturing silicon-based micro display screen as claimed in claim 8, wherein the etching chamber comprises a first etching chamber for etching the first protective layer and the second protective layer, a second etching chamber for etching the cathode layer, and a third etching chamber for etching the OLED layer.

11. A silicon-based micro display screen, comprising a silicon substrate, a plurality of sub-pixel formed on the silicon substrate and an encapsulation layer completely covering the silicon substrate and the sub-pixels, the sub-pixel comprising an anode layer, OLED layer, a cathode layer, a first protective layer and a second protective layer, the second protective layer arranged at sides of the anode layer, the OLED layer, the cathode layer and the first protective layer, wherein the silicon-based micro display screen is manufactured by method of manufacturing silicon-based micro display screen as claimed in claim 1.

12. The silicon-based micro display screen as claimed in claim 11, further comprising a cathode connection layer, wherein the first protective layer is provided with a conductive hole penetrated therethrough, the cathode connection layer is disposed in the conductive hole and gap between the sub-pixels, and wherein the sub-pixel pitch is 8 micrometers.

13. The silicon-based micro display screen as claimed in claim 12, wherein the material of the cathode layer is aluminum, the material of the first protective layer is SiO₂, and the material of the second protective layer is SiN, and the material of the encapsulation layer is SiO₂.

14. The silicon-based micro display screen as claimed in claim 11, wherein the OLED layer comprises an organic light emitting layer, a hole injection layer and a hole transport layer located between the anode layer and the organic light emitting layer, and an electron injection layer and an electron transport layer located between the cathode layer and the organic light emitting layer.

15. The silicon-based micro display screen as claimed in claim 11, wherein the step S1 specifically comprises following steps:
S11: providing a silicon substrate, defining a plurality of sub-pixel regions on the silicon substrate, and preparing a plurality of regularly arranged via holes in the sub-pixel region;
S12: evaporating an anode layer on the silicon substrate by using a self-aligning process, wherein the anode layer comprises anode units corresponding to the via holes one-to-one, and the width of the anode unit is 5 micrometers.

16. The silicon-based micro display screen as claimed in claim 11, wherein the etching process in step S3 and step S4, S5 are performed in a vacuum environment, and wherein the etching process is a reactive ion etching process, the process temperature of the yellowing process is lower than 90° C., and the plasma is argon ion.

17. The silicon-based micro display screen as claimed in claim 11, wherein the step S5 specifically comprises following steps:
S51: forming a second protective layer, which covers the first protective layer and the silicon substrate;
S52: etching the second protective layer by using the Spacer etching process so that only the portions of the second protective layer located on the sides of the anode layer, the OLED layer, the cathode layer and the first protective layer are remained.

18. The silicon-based micro display screen as claimed in claim 11, wherein the step S7 specifically comprises:
S71: forming conductive holes penetrating each first protective layer;
S72: forming a cathode connection layer in the conductive hole and gap between sub-pixels to connect the cathode layer of each sub-pixel;
S73: forming an encapsulation layer covering the silicon substrate and each sub-pixel.

19. The silicon-based micro display screen as claimed in claim 18, wherein the cathode connection layer of S72 is formed by an atomic layer deposition method, and the material is aluminum, and the thickness of the cathode connecting layer is 10 mm.

20. The silicon-based micro display screen as claimed in claim 16, wherein the etching process of step S3, and steps S4 and S5 are performed in an etching and coating linkage system, which comprises a transfer chamber, an etching chamber connected to the transfer chamber and a coating chamber, and wherein inside of the etching and coating linkage system is in vacuum state.
